(19) United States
(12) Patent Application Publication
(10) Pub. No.: US 2022/0130874 A1
(43) Pub. Date: Apr. 28, 2022

(54) LOW-LATENCY THIN FILM TRANSISTOR, ARRAY SUBSTRATE, AND DISPLAY PANEL

(71) Applicant: Shenzhen China Star Optoelectronics Semiconductor Display Technology Co., Ltd., Shenzhen, Guangdong (CN)

(72) Inventors: Munan LIN, Shenzhen, Guangdong (CN); Bangyin PENG, Shenzhen, Guangdong (CN); Ilgon KIM, Shenzhen, Guangdong (CN)

(21) Appl. No.: 16/954,096

(22) PCT Filed: Jun. 2, 2020
(86) PCT No.: PCT/CN2020/093894

§ 371 Date: Jun. 16, 2020

(30) Foreign Application Priority Data
May 18, 2020 (CN) 2020 10418772.2

(51) Int. Cl. H01L 27/12; G02F 1/1362

(52) U.S. Cl. CPC H01L 27/1251; G02F 1/136222; H01L 27/1218; H01L 27/1237

(57) ABSTRACT

The present invention provides a low-latency thin film transistor, an array substrate, and a display panel. The low-latency thin film transistor includes a gate, an active layer disposed on a side of the gate, and a source and a drain disposed above the gate, and the source and the drain are respectively connected to the active layer, wherein in a direction perpendicular to the active layer, at least part of an orthographic projection of the drain is located outside an orthographic projection of the gate.

### FIELD OF INVENTION

The present disclosure relates to the field of display technology, and more particularly, to a low-latency thin film transistor, an array substrate, and a display panel.

### BACKGROUND OF INVENTION

With development of display technology, in high refresh rate (such as 120 Hz) and high-resolution (such as 8K pixels) liquid crystal display panels, signal delay is a key factor restricting further development of the liquid crystal display panels. In thin film transistors (TFTs), a capacitance between a gate and a source/drain is directly affected by an overlapping area thereof.

### SUMMARY OF INVENTION

At present, in a structure of thin film transistors, an entire drain is disposed on a gate metal, and an overlapping area of the drain and the gate is large, resulting in a large coupling capacitance between the drain and the gate, which causes a large delay in a resistor-capacitor of a display panel, thereby affecting display performance of the display panel.

The present disclosure provide a low-latency thin film transistor, an array substrate, and a display panel to solve the problem that in a structure of current thin film transistors, the overlapping area of the drain and the gate is large, resulting in a large coupling capacitance between the drain and the gate, which causes a large delay in the resistor-capacitor of the display panel, thereby affecting display performance of the display panel.

In order to solve the above problems, technical solutions provided by the present disclosure are as follows.

The present disclosure provides a low-latency thin film transistor. The low-latency thin film transistor comprises a gate, an active layer disposed on a side of the gate, and a source and a drain disposed above the gate, and the source and the drain are respectively connected to the active layer, wherein in a direction perpendicular to the active layer, at least part of an orthographic projection of the drain is located outside an orthographic projection of the gate.

In the low-latency thin film transistor provided by the present disclosure, an orthographic projection of an end of the drain away from the source in the direction perpendicular to the active layer is located outside the orthographic projection of the gate in the direction perpendicular to the active layer.

In the low-latency thin film transistor provided by the present disclosure, the drain is a U-shaped structure, the drain comprises a connection portion, and a first side and a second side respectively extending from both ends of the connection portion, the source is disposed between the first side and the second side, and at least part of an orthographic projection of the connection portion in the direction perpendicular to the active layer is located outside the orthographic projection of the gate in the direction perpendicular to the active layer.

In the low-latency thin film transistor provided by the present disclosure, the active layer covers a region between the source and the first side, and the active layer covers a region between the source and the second side.

In the low-latency thin film transistor provided by the present disclosure, the source extends close to the connection portion.

In the low-latency thin film transistor provided by the present disclosure, the low-latency thin film transistor further comprises a gate insulating layer disposed on the gate, and the active layer is disposed on the gate insulating layer.

In the low-latency thin film transistor provided by the present disclosure, the low-latency thin film transistor further comprises a gate insulating layer disposed on the active layer, wherein the gate is disposed on the gate insulating layer, and an interlayer insulating layer disposed on the gate insulating layer and covering the gate, wherein the source and the drain are respectively electrically connected to the active layer through the interlayer insulating layer.

The present disclosure further provides an array substrate comprising the low-latency thin film transistor in the above embodiments, and the array substrate comprises a base substrate and a plurality of pixel units distributed in an array on the base substrate, each pixel unit at least comprises a main pixel electrode, a sub-pixel electrode, a first thin film transistor electrically connected to the main pixel electrode, and a second thin film transistor electrically connected to the sub-pixel electrode, wherein the first thin film transistor or/and the second thin film transistor are the low-latency thin film transistors.

In the array substrate provided by the present disclosure, an orthographic projection of an end of the drain away from the source in the direction perpendicular to the active layer is located outside the orthographic projection of the gate in the direction perpendicular to the active layer.

In the array substrate provided by the present disclosure, the drain is a U-shaped structure, the drain comprises a connection portion, and a first side and a second side respectively extending from both ends of the connection portion, the source is disposed between the first side and the second side, and at least part of an orthographic projection of the connection portion in the direction perpendicular to the active layer is located outside the orthographic projection of the gate in the direction perpendicular to the active layer.

In the array substrate provided by the present disclosure, the active layer covers a region between the source and the first side, and the active layer covers a region between the source and the second side.

In the array substrate provided by the present disclosure, the source extends close to the connection portion.

In the array substrate provided by the present disclosure, the low-latency thin film transistor further comprises a gate insulating layer disposed on the gate, and the active layer is disposed on the gate insulating layer.

In the array substrate provided by the present disclosure, the low-latency thin film transistor further comprises a gate insulating layer disposed on the active layer, wherein the gate is disposed on the gate insulating layer, and an interlayer insulating layer disposed on the gate insulating layer and covering the gate, wherein the source and the drain are respectively electrically connected to the active layer through the interlayer insulating layer.

In the array substrate provided by the present disclosure, the array substrate comprises a third thin film transistor connected to the second thin film transistor, and the third thin film transistor is the low-latency thin film transistor.

The present disclosure further provides a display panel, and the display panel comprises a color film substrate and the array substrate in the above embodiments, and a liquid crystal layer is disposed between the color film substrate and the array substrate.

In the display panel provided by the present disclosure, the array substrate comprises a third thin film transistor connected to the second thin film transistor, and the third thin film transistor is the low-latency thin film transistor.

In the display panel provided by the present disclosure, an orthographic projection of an end of the drain away from the source in the direction perpendicular to the active layer is located outside the orthographic projection of the gate in the direction perpendicular to the active layer.

In the display panel provided by the present disclosure, the drain is a U-shaped structure, the drain comprises a connection portion, and a first side and a second side respectively extending from both ends of the connection portion, the source is disposed between the first side and the second side, and at least part of an orthographic projection of the connection portion in the direction perpendicular to the active layer is located outside the orthographic projection of the gate in the direction perpendicular to the active layer.

In the display panel provided by the present disclosure, the active layer covers a region between the source and the first side, and the active layer covers a region between the source and the second side.

Beneficial effects of the present disclosure are that at least part of the drain extends outside a region where the gate is located, so that in the direction perpendicular to the active layer, at least part of the orthographic projection of the drain is located outside the orthographic projection of the gate, which reduces an overlapping area of the drain and the gate, a coupling capacitance between the drain and the gate, and delay in a resistor-capacitor, and improves display performance of the display panel.

### DESCRIPTION OF DRAWINGS

In order to illustrate technical solutions of the embodiments or prior art more clearly, drawings used in a description of the embodiments will be briefly described as below. Obviously, the drawings described as below are just some embodiments of the present disclosure. For those of ordinary skill in the art, under a premise of no creative labor, other drawings can also be obtained according to these drawings.

FIG. 1 is a schematic structural diagram of a low-latency thin film transistor in an embodiment of the present disclosure.

FIG. 2 is a schematic structural diagram of a bottom-gate structure of the low-latency thin film transistor in the embodiment of the present disclosure.

FIG. 3 is a schematic structural diagram of a top-gate structure of the low-latency thin film transistor in the embodiment of the present disclosure.

FIG. 4 is a schematic structural diagram of an array substrate in the embodiment of the present disclosure.

FIG. 5 is a schematic structural diagram of a display panel in the embodiment of the present disclosure.

### DETAILED DESCRIPTION OF PREFERRED EMBODIMENTS

The following description of the embodiments with reference to the appended drawings is used for illustrating specific embodiments which may be used for carrying out the present disclosure. The directional terms described by the present disclosure, such as “upper”, “lower”, “front”, “back”, “left”, “right”, “inner”, “outer”, “side”, etc., are only directions by referring to the accompanying drawings. Thus, the adopted directional terms are used to describe and understand the present disclosure, but the present disclosure is not limited thereto. In figures, elements with similar structures are indicated by the same numbers.

In descriptions of the present disclosure, it should be noted that, orientations or position relationships indicated by the terms, such as “center”, “longitudinal”, “transverse”, “length”, “width”, “thickness”, “upper”, “lower”, “front”, “back”, “left”, “right”, “vertical”, “horizontal”, “top”, “bottom”, “inside”, “outside”, “clockwise”, “counterclockwise”, etc. are based on the orientations or position relationships shown in the drawings. These are only convenience for describing the present disclosure and simplifying the descriptions, and does not indicate or imply that the device or element must have a specific orientation, a structure and an operation in the specific orientation, so it cannot be understood as a limitation on the present disclosure. In addition, the terms “first” and “second” are used for describing purposes only, and cannot be understood as indicating or implying relative importance or implicitly indicating the number of technical features indicated. Thus, the features defined as “first” and “second” may explicitly or implicitly include one or more of the features. In the descriptions of the present disclosure, the meaning of “plurality” is two or more, unless it is specifically defined otherwise.

In the present disclosure, the terms “mounting”, “connected”, “fixed” and the like should be broadly understood unless expressly stated or limited otherwise. For example, it may be fixed connected, removably connected, or integrated; it may be mechanically connected, or an electrically connected; it may be directly connected, or indirectly connected through an intermediary; it may be a connection between two elements or an interaction between two elements. For those skilled in the art, the specific meanings of the above terms in the present disclosure may be understood based on specific situations.

In the present disclosure, unless explicitly stated and defined otherwise, the first feature may be “above” or “below” the second feature and may include direct contact between the first and second features. It may also include that the first and second features are not in direct contact but are contacted by another feature between them. Moreover, the first feature is “above” the second feature, including the first feature directly above and obliquely above the second feature, or merely indicates that the first feature is higher in level than the second feature. The first feature is “below” the second feature, including the first feature is directly below and obliquely below the second feature, or only indicates that the first feature is less horizontal than the second feature.

The following disclosure provides many different embodiments or examples for achieving different structures of the present disclosure. To simplify the present disclosure, components and settings of specific examples are described below. They are only examples and are not intended to limit the present disclosure. In addition, the present disclosure may repeat reference numbers and/or reference letters in different examples, this repetition is for the purpose of simplicity and clarity, and does not itself indicate the relationship between various embodiments and/or settings discussed. In addition, the present disclosure provides examples of various specific processes and materials, but those of ordinary skill in the art may be aware of the present disclosure of other processes and/or the use of other materials.

The technical solution of the present disclosure will now be described in conjunction with specific embodiments.

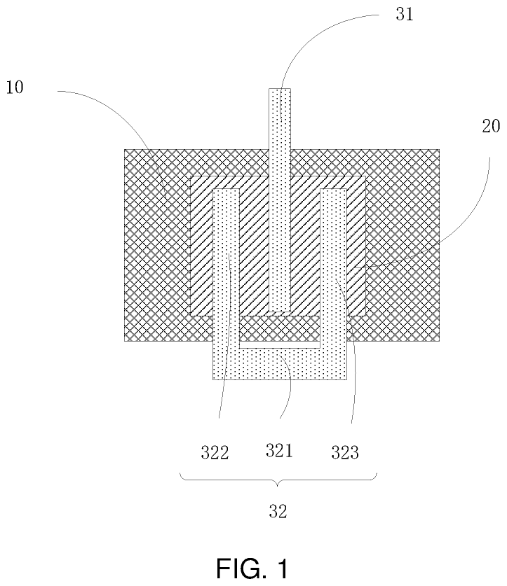

The present disclosure provides a low-latency thin film transistor, as shown in FIG. 1, the low-latency thin film transistor comprises a gate 10, an active layer 20 disposed on a side of the gate 10, and a source 31 and a drain 32 disposed above the gate 10, wherein the source 31 and the drain 32 are respectively connected to the active layer 20, wherein in a direction perpendicular to the active layer 20, at least part of an orthographic projection of the drain 32 is located outside an orthographic projection of the gate 10.

It should be understood that in high refresh rate (such as 120 Hz) and high-resolution (such as 8K pixels) liquid crystal display panels, signal delay is a key factor restricting further development of the liquid crystal display panels. In thin film transistors (TFTs), a capacitance between a gate and a source/drain is directly affected by an overlapping area thereof. In a structure of current thin film transistors, the overlapping area of the drain and the gate is large, resulting in a large coupling capacitance between the drain and the gate, which causes a large delay in a resistor-capacitor of the display panel, thereby affecting display performance of the display panel. In the present disclosure, at least part of the drain 32 extends outside a region where the gate 10 is located, so that in the direction perpendicular to the active layer 20, at least part of the orthographic projection of the drain 32 is located outside the orthographic projection of the gate 10, which reduces the overlapping area of the drain 32 and the gate 10, the coupling capacitance between the drain and the gate 10, and delay in a resistor-capacitor, and improves display performance of the display panel.

Moreover, in the present embodiment, the overlapping area of the drain 32 and the gate 10 in the direction perpendicular to the active layer 20 is reduced, that is, an area directly facing the drain 32 and the gate 10 is reduced. Therefore, when the low-latency thin film transistor is charged and discharged, the coupling capacitance between the drain 32 and the gate 10 is reduced, an impedance of the resistor-capacitor of the low-latency thin-film transistor is reduced, and delay time of the low-latency thin-film transistor is reduced.

In one embodiment, as shown in FIG. 1, an orthographic projection of an end of the drain 32 away from the source 31 in the direction perpendicular to the active layer 20 is located outside the orthographic projection of the gate 10 in the direction perpendicular to the active layer 20. It should be understood that in order to facilitate response of the thin film transistor, the gate 10 generally has a larger coverage area, the gate 10 at least covers the active layer 20, and the orthographic projection of one end of the drain 32 away from the source 31 in the direction perpendicular to the active layer 20 is located outside the orthographic projection of the gate 10 in the direction perpendicular to the active layer 20, which ensure that a structure for reducing an area facing the drain 32 and the gate 10 is realized under a condition that a channel size between the source 31 and the drain 32 is not affected to the greatest extent, thereby minimizing device performance of other aspects of the low-latency thin film transistors.

In one embodiment, as shown in FIG. 1, the drain 32 is a U-shaped structure, the drain 32 comprises a connection portion 321, and a first side 322 and a second side 323 respectively extending from both ends of the connection portion 321. The source 31 is disposed between the first side 322 and the second side 323, and at least part of an orthographic projection of the connection portion 321 in the direction perpendicular to the active layer 20 is located outside the orthographic projection of the gate 10 in the direction perpendicular to the active layer 20. It should be understood that current drain 32 with the U-shaped structure is generally entirely covered by the region where the gate 10 is located. In the present disclosure, the drain 32 comprises the connection portion 321, and the first side 322 and the second side 323 respectively extending from both ends of the connection portion 321, that is, the end of the drain 32 with the U-shaped structure away from the source 31 is disposed outside the region covered by the gate 10, and portions of the first side 322 and the second side 323 close to the connecting portion 321 may also extend outside the region covered by the gate 10. Specifically, the connection portion 321 is entirely or partially disposed outside the region covered by the gate 10, and can be disposed according to specific circumstances, and is not limited herein.

In one embodiment, as shown in FIG. 1, the active layer 20 covers a region between the source 31 and the first side 322, and the active layer 20 covers a region between the source 31 and the second side 323. It should be understood that in order to not affect device performance of the low-latency thin film transistor, the active layer 20 cannot be disposed outside the region covered by the gate 10, which affects normal switching performance of the region between the connection portion 321 and the source 31 in an original U-shaped channel structure under a condition that an orthographic projection of a part of the connection portion 321 in the direction perpendicular to the active layer 20 is located outside the orthographic projection of the gate 10 in the direction perpendicular to the active layer 20. In the present embodiment, a first channel region is defined between the source 31 and the first side 322, a second channel region is defined between the source 31 and the second side 323, and the active layer 20 covers the first channel region and the second channel region to maintain device performance of the low-latency thin film transistor at the first side 322 and the second side 323.

Moreover, in one embodiment, the source 31 extends close to the connection portion 321. It should be understood that the source 31 extends close to the connecting portion 321, so that a channel length of the first channel region defined between the source 31 and the first side 322 is increased, and a channel length of the second channel region defined between the source 31 and the second side 323 is also increased, which compensates for loss of channel between the connection portion 321 and the source 31, thereby minimizing an impact on other performance of the thin film transistors.

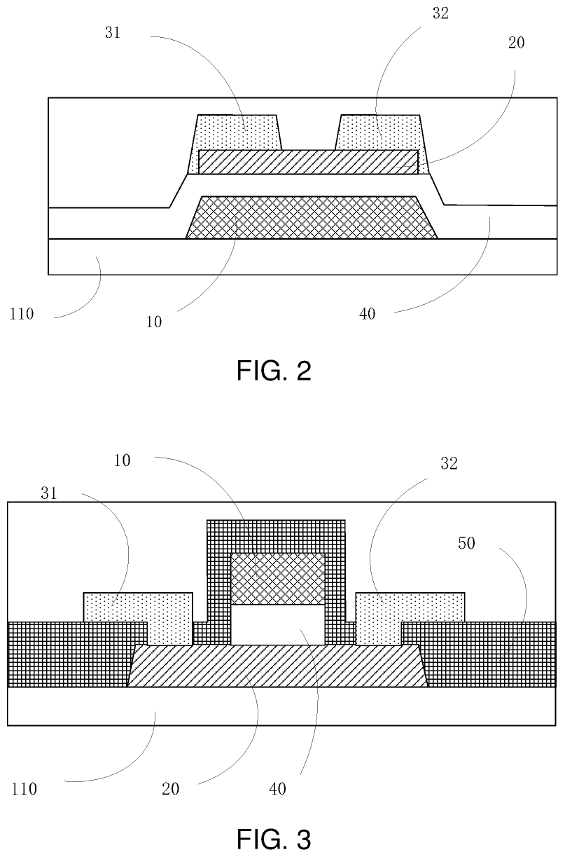

In one embodiment, as shown in FIG. 2, the low-latency thin film transistor may be a bottom-gate structure, and the low-latency thin film transistor further comprises a gate insulating layer 40 disposed on the gate 10, and the active layer 20 is disposed on the gate insulating layer 40.

In one embodiment, the low-latency thin film transistor may be a top-gate structure, the low-latency thin film transistor further comprises a gate insulating layer 40 disposed on the active layer 20, wherein the gate 10 is disposed on the gate insulating layer 40, and an interlayer insulating layer 50 disposed on the gate insulating layer 40 and covering the gate 10, wherein the source 31 and the drain 32 are respectively electrically connected to the active layer 20 through the interlayer insulating layer 50.

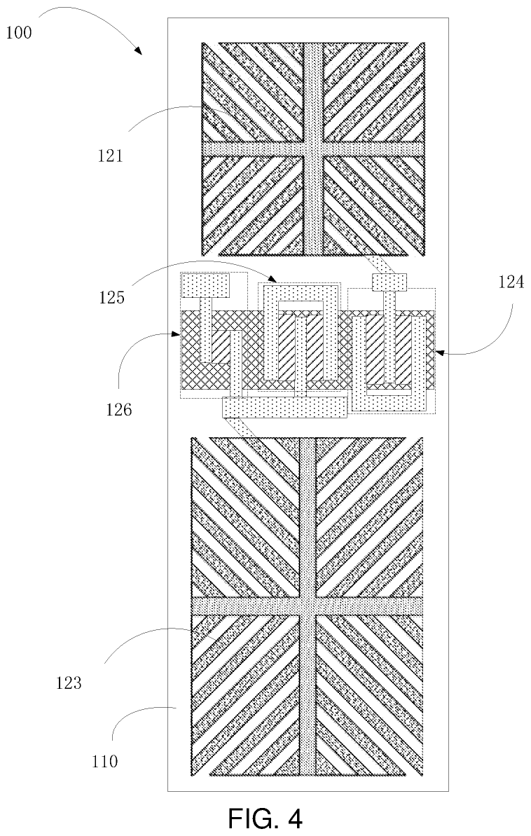

The present disclosure further provides an array substrate 100, as shown in FIG. 4, comprising the low-latency thin film transistor in the above embodiments, the array substrate 100 comprises a base substrate 110 and a plurality of pixel units distributed in an array on the base substrate 110. Each pixel unit at least comprises a main pixel electrode 121, a sub-pixel electrode 123, a first thin film transistor 124 electrically connected to the main pixel electrode 121, and a second thin film transistor 125 electrically connected to the sub-pixel electrode 123, wherein the first thin film transistor 124 or/and the second thin film transistor 125 are the low-latency thin film transistors.

It should be understood that the first thin film transistor 124 and/or the second thin film transistor 125 are the low-latency thin film transistors, which is beneficial to reduce delay in resistor-capacitors of the first thin film transistor 124 electrically connected to the main pixel electrode 121 and/or the second thin film transistor 125 electrically connected to the sub-pixel electrode 123 and improve working efficiency of the array substrate 100. In addition, the array substrate 100 further comprises a third thin film transistor 126 connected to the second thin film transistor 125, and the third thin film transistor 126 is the low-latency thin film transistor. Especially, when the third thin film transistor 126 is a U-shaped channel structure (not shown in the figure), response performance of the third thin film transistor 126 can be further improved.

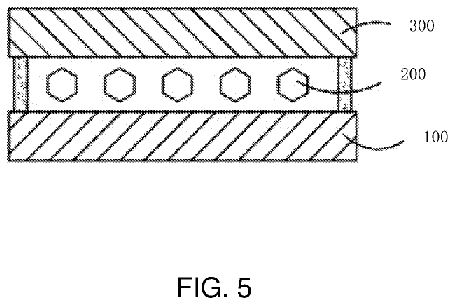

The present disclosure further provides display panel, as shown in FIG. 5. The display panel comprises a color film substrate 300 and the array substrate 100 in the above embodiment, and a liquid crystal layer 200 is disposed between the color film substrate 300 and the array substrate 100.

In summary, in the present disclosure, at least part of the drain 32 extends outside the region where the gate 10 is located, so that in the direction perpendicular to the active layer 20, at least part of the orthographic projection of the drain 32 is located outside the orthographic projection of the gate 10, which reduces the overlapping area of the drain 32 and the gate 10, the coupling capacitance between the drain and the gate 10, and delay in the resistor-capacitor, and improves display performance of the display panel.

As mentioned above, while the present disclosure has been disclosed via preferred embodiments as above, the preferred embodiments are not intended to limit the disclosure. Those skilled in the art can make various modifications and alternations without departing from the spirit and scope of the disclosure. The scope of protection of the disclosure is defined by the claims.

What is claimed is:

1. A low-latency thin film transistor, comprising a gate, an active layer disposed on a side of the gate, and a source and a drain disposed above the gate, wherein the source and the drain are respectively connected to the active layer;
wherein in a direction perpendicular to the active layer, at least part of an orthographic projection of the drain is located outside an orthographic projection of the gate.

2. The low-latency thin film transistor as claimed in claim 1, wherein an orthographic projection of an end of the drain away from the source in the direction perpendicular to the active layer is located outside the orthographic projection of the gate in the direction perpendicular to the active layer.

3. The low-latency thin film transistor as claimed in claim 2, wherein the drain is a U-shaped structure, the drain comprises a connection portion, and a first side and a second side respectively extending from both ends of the connection portion, the source is disposed between the first side and the second side, and at least part of an orthographic projection of the connection portion in the direction perpendicular to the active layer is located outside the orthographic projection of the gate in the direction perpendicular to the active layer.

4. The low-latency thin film transistor as claimed in claim 3, wherein the active layer covers a region between the source and the first side; and
the active layer covers a region between the source and the second side.

5. The low-latency thin film transistor as claimed in claim 3, wherein the source extends close to the connection portion.

6. The low-latency thin film transistor as claimed in claim 1, wherein the low-latency thin film transistor comprises a gate insulating layer disposed on the gate, and the active layer is disposed on the gate insulating layer.

7. The low-latency thin film transistor as claimed in claim 1, wherein the low-latency thin film transistor comprises a gate insulating layer disposed on the active layer, wherein the gate is disposed on the gate insulating layer; and
an interlayer insulating layer disposed on the gate insulating layer and covering the gate, wherein the source and the drain are respectively electrically connected to the active layer through the interlayer insulating layer.

8. An array substrate, comprising the low-latency thin film transistor as claimed in claim 1, wherein the array substrate comprises a base substrate and a plurality of pixel units distributed in an array on the base substrate, each pixel unit at least comprises a main pixel electrode, a sub-pixel electrode, a first thin film transistor electrically connected to the main pixel electrode, and a second thin film transistor electrically connected to the sub-pixel electrode;
wherein the first thin film transistor or/and the second thin film transistor are the low-latency thin film transistors.

9. The array substrate as claimed in claim 8, wherein an orthographic projection of an end of the drain away from the source in the direction perpendicular to the active layer is located outside the orthographic projection of the gate in the direction perpendicular to the active layer.

10. The array substrate as claimed in claim 9, wherein the drain is a U-shaped structure, the drain comprises a connection portion, and a first side and a second side respectively extending from both ends of the connection portion, the source is disposed between the first side and the second side, and at least part of an orthographic projection of the connection portion in the direction perpendicular to the active layer is located outside the orthographic projection of the gate in the direction perpendicular to the active layer.

11. The array substrate as claimed in claim 10, wherein the active layer covers a region between the source and the first side; and
the active layer covers a region between the source and the second side.

12. The array substrate as claimed in claim 10, wherein the source extends close to the connection portion.

13. The array substrate as claimed in claim 8, wherein the low-latency thin film transistor comprises a gate insulating layer disposed on the gate, and the active layer is disposed on the gate insulating layer.

14. The array substrate as claimed in claim 8, wherein the low-latency thin film transistor comprises a gate insulating layer disposed on the active layer, wherein the gate is disposed on the gate insulating layer; and
an interlayer insulating layer disposed on the gate insulating layer and covering the gate, wherein the source and the drain are respectively electrically connected to the active layer through the interlayer insulating layer.

15. The array substrate as claimed in claim 8, wherein the array substrate comprises a third thin film transistor connected to the second thin film transistor, and the third thin film transistor is the low-latency thin film transistor.

16. A display panel, wherein the display panel comprises a color film substrate and the array substrate as claimed in claim 8, and a liquid crystal layer is disposed between the color film substrate and the array substrate.

17. The display panel as claimed in claim 16, wherein the array substrate comprises a third thin film transistor connected to the second thin film transistor, and the third thin film transistor is the low-latency thin film transistor.

18. The display panel as claimed in claim 16, wherein an orthographic projection of an end of the drain away from the source in the direction perpendicular to the active layer is located outside the orthographic projection of the gate in the direction perpendicular to the active layer.

19. The display panel as claimed in claim 18, wherein the drain is a U-shaped structure, the drain comprises a connection portion, and a first side and a second side respectively extending from both ends of the connection portion, the source is disposed between the first side and the second side, and at least part of an orthographic projection of the connection portion in the direction perpendicular to the active layer is located outside the orthographic projection of the gate in the direction perpendicular to the active layer.

20. The display panel as claimed in claim 19, wherein the active layer covers a region between the source and the first side; and
the active layer covers a region between the source and the second side.
